(19) United States
(12) Patent Application Publication
(10) Pub. No.: US 2014/0197549 A1
(43) Pub. Date: Jul. 17, 2014

(54) SEMICONDUCTOR PACKAGE AND METHOD OF MANUFACTURING THE SAME

(71) Applicant: Samsung Electronics Co., Ltd., Suwon-Si (KR)

(72) Inventor: Seok-Won JEONG, Daejeon (KR)

(73) Assignee: SAMSUNG ELECTRONICS CO., LTD., Suwon-Si (KR)

(21) Appl. No.: 14/154,390

(22) Filed: Jan. 14, 2014

(30) Foreign Application Priority Data
Jan. 14, 2013 (KR) 10-2013-0003933

(51) Int. Cl. H01L 21/56; H01L 23/31

(52) U.S. Cl. CPC H01L 21/565; H01L 23/3107
USPC 257/782; 438/112

(57) ABSTRACT

A semiconductor package includes a package substrate, a semiconductor chip, a die attach film, a molding member, and a dummy finger. A bond finger is arranged on an upper surface of the package substrate. The semiconductor chip is arranged on the upper surface of the package substrate, and electrically connected to the bond finger. The die attach film is interposed between the semiconductor chip and the package substrate such that the semiconductor chip is attached to the package substrate. The molding member is formed on the upper surface of the package substrate to cover the semiconductor chip. The dummy finger is formed between the upper surface of the package substrate and the molding member. Moisture in the void formed in the die attach film may be released through the discharge passageway. Thus, the package substrate is prevented from being swollen during a subsequent thermal process such as a reflow process.

### CROSS-RELATED APPLICATION

This application claims priority under 35 USC §119 to Korean Patent Application No. 2013-3933, filed on Jan. 14, 2013 in the Korean Intellectual Property Office (KIPO), the contents of which are herein incorporated by reference in their entirety.

### BACKGROUND

1. Field

Example embodiments relate to semiconductor packages and/or methods of manufacturing the same. More particularly, example embodiments relate to semiconductor packages including a semiconductor chip and a package substrate attached to each other using a die attach film, and/or methods of manufacturing the semiconductor package.

2. Description of the Related Art

Generally, various semiconductor fabrication processes may be performed on a wafer having a plurality of semiconductor chips. In order to mount the semiconductor chips on a printed circuit board (PCB), a packaging process may be performed on the semiconductor chip to form a semiconductor package.

The semiconductor package may include a package substrate, a semiconductor chip, a die attach film and a molding member. The semiconductor chip may be attached to an upper surface of the package substrate using the die attach film. The package substrate may include a bond finger electrically connected to the semiconductor chip. The molding member may be formed on the upper surface of the package substrate to cover the semiconductor chip.

A void may be formed in the die attach film due to a rugged upper surface of the package substrate. Air and/or moisture may accumulate in the void. The moisture in the void may expand during a reflow process for forming external terminals and cause, e.g., a swelling of the package substrate.

### SUMMARY

Example embodiments provide semiconductor packages capable of preventing or mitigating a swelling of a package substrate.

Example embodiments also provide methods of manufacturing the above-mentioned semiconductor package.

According to example embodiments, a semiconductor package may include a package substrate including at least one bond finger, a semiconductor chip, a die attach film, a molding member, and at least one dummy finger. The at least one bond finger may be arranged on an upper surface of the package substrate. The semiconductor chip may be arranged on the upper surface of the package substrate, and may be electrically connected with the bond finger. The die attach film may be interposed between the semiconductor chip and the package substrate such that the semiconductor chip is attached to the package substrate. The molding member may be formed on the upper surface of the package substrate to cover the semiconductor chip. The at least one dummy finger may be formed between the upper surface of the package substrate and the molding member.

The at least one dummy finger and the molding member are configured to not closely adhere to each other such that at least one discharge passageway is formed therebetween.

The at least one dummy finger may extends from the die attach film to an outer surface of the molding member. The at least one discharge passageway may be exposed through the outer surface of the molding member.

The at least one discharge passageway may extend between the die attach film and an outer surface of the molding member. One end of the at least one discharge passageway may be enclosed by the molding member.

The at least one dummy finger may include a metal, e.g., gold.

The at least one dummy finger and the at least one bond finger may include substantially a same material.

The semiconductor package may further include a conductive wire, which is configured to electrically connect the semiconductor chip to the at least one bond finger.

The semiconductor package may further include an external terminal mounted on a lower surface of the package substrate.

According to example embodiments, the method of manufacturing the semiconductor package, at least one bond finger may be formed on an upper surface of the package substrate. At least one dummy finger may be formed on the upper surface of the package substrate. A semiconductor chip may be attached to the upper surface of the package substrate using a die attach film. The semiconductor chip may be electrically connected to the at least one bond finger. The molding member may be formed on the upper surface of the package substrate to cover the semiconductor chip and the at least one dummy finger. The at least one dummy finger includes a material that does not closely adhere to the molding member to form at least one first discharge passageway between the at least one dummy finger and the molding member.

The method may further include performing a heat process to release air or moisture in a void, which is formed in the die attach film, through the at least one first discharge passageway.

The at least one bond finger may be formed simultaneously with the at least one dummy finger.

The at least one bond finger and the at least one dummy finger may be simultaneously formed by a single plating process.

Forming the molding member may include arranging a plurality of the package substrates on a substrate frame, forming the molding member on the package substrates, and separating the substrate frame into individual package substrates. The at least one first discharge passageway of each of the individual substrate may be exposed through an outer surface of the molding member.

Forming the molding member may include arranging a plurality of the package substrates on a substrate frame having at least one second discharge passageway, the at least one second passageway in communication with the at least one first discharge passageway, forming the molding member on the package substrates to releasing air or moisture in the void through the at least one first discharge passageway and the at least one second discharge passageway, separating the substrate frame into individual package substrates, and enclosing the at least one second discharge passageway.

The method may further include forming a conductive wire electrically connecting the semiconductor chip to the at least one bond finger.

The method may further include mounting an external terminal on a lower surface of the package substrate.

According to example embodiments, the at least one dummy finger, which may not closely adhere to or be chemically well-bonded to the molding member, may be formed on the package substrate to form the at least one discharge passageway between the molding member and the dummy finger. Thus, the moisture in the void formed in the die attach film may be released through the at least one discharge passageway, thereby preventing or mitigating, for instance, a swelling of the package substrate during a reflow process. Further, the air in the void may also be released through the at least one discharge passageway, thereby removing or reducing the void in the die attach film. Furthermore, because the at least one dummy finger and the at least one bond finger may be formed by the single plating process, an additional process for forming the dummy finger may not be required.

According to example embodiments, a semiconductor package may include a package substrate including at least one bond finger, a semiconductor chip on the bond finger, the semiconductor chip electrically connected to the package substrate through the bond finger, a die attach film between the semiconductor chip and the package substrate, the die attach film attaching the semiconductor chip to the package substrate, a molding member on the package substrate, and at least one dummy finger between the package substrate and the molding member and surrounding the die attach film, the at least one dummy finger configured to not closely adhere to the molding member to provide at least one discharge passage between the at least one dummy finger and the at least one molding member.

One end of the at least one discharge passageway may be exposed through an outer surface of the molding member.

The at least one discharge passageway facing an outer surface of the molding member may be enclosed, e.g., by the molding member.

The at least one dummy finger and the at least one bond finger includes substantially a same material.

### BRIEF DESCRIPTION OF THE DRAWINGS

Example embodiments will be more clearly understood from the following detailed description taken in conjunction with the accompanying drawings. FIGS. 1 to 9 represent non-limiting, example embodiments as described herein.

FIG. 1 is across-sectional view illustrating a semiconductor package in accordance with example embodiments;

FIG. 2 is a plan view illustrating the semiconductor package in FIG. 1;

FIGS. 3 to 6 are cross-sectional views and a plan view illustrating a method of manufacturing the semiconductor package in FIG. 1;

FIG. 7 is a cross-sectional view illustrating a semiconductor package in accordance with example embodiments; and

FIGS. 8 and 9 are a cross-sectional view and a plan view illustrating a method of manufacturing the semiconductor package in FIG. 7.

### DETAILED DESCRIPTION OF EXAMPLE EMBODIMENTS

Various example embodiments will be described more fully hereinafter with reference to the accompanying drawings, in which some example embodiments are shown. Example embodiments may, however, be embodied in many different forms and should not be construed as limited to the example embodiments set forth herein. Rather, these example embodiments are provided so that this disclosure will be thorough and complete, and will fully convey the scope of the example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, an example term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which these example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

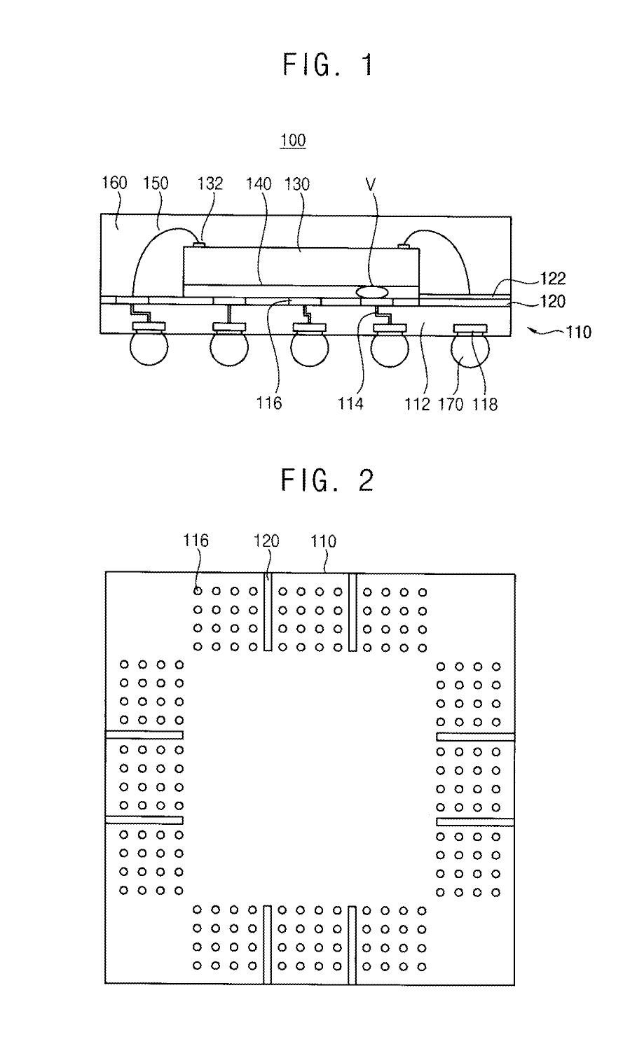

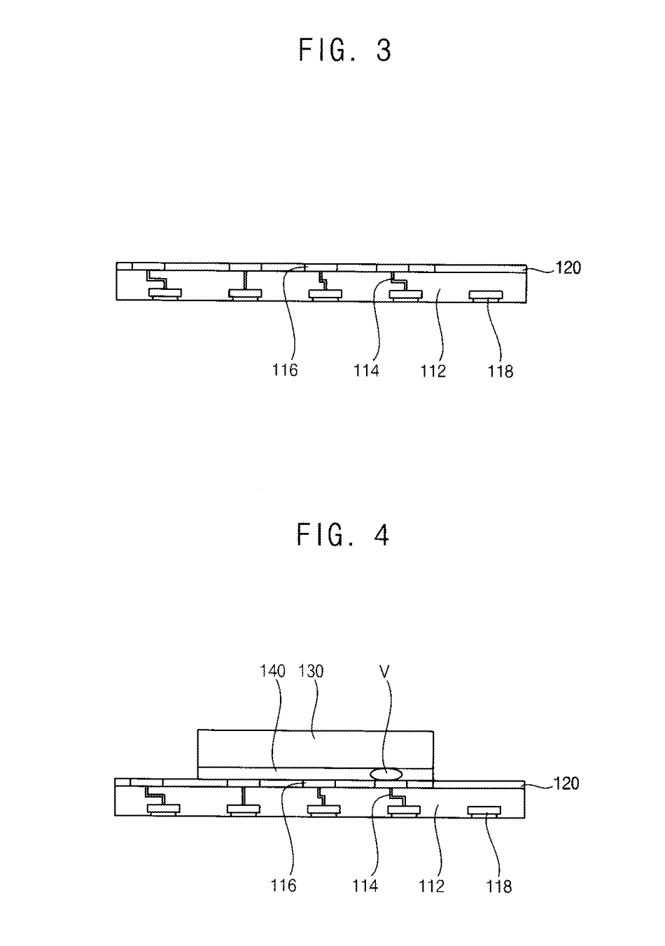

FIG. 1 is a cross-sectional view illustrating a semiconductor package in accordance with example embodiments, and FIG. 2 is a plan view illustrating the semiconductor package in FIG. 1.

Referring to FIGS. 1 and 2, a semiconductor package 100 of example embodiments may include a package substrate 110, a dummy finger 120, a semiconductor chip 130, a die attach film 140, a conductive wire 150, a molding member 160 and/or external terminals 170.

The package substrate 110 may include an insulating substrate 112, a contact plug 114, a bond finger 116 and a ball land 118. For example, the insulating substrate 112 may include an insulating material chemically well-bonded to (e.g., closely adhered to) the molding member 160. The contact plug 114 may be formed in the insulating substrate 112. The contact plug 114 may be exposed through a photosensitive resist (not shown) formed on an upper surface and a lower surface of the insulating substrate 112.

The bond finger 116 may be formed on the upper surface of the insulating substrate 112. The bond finger 116 may be electrically connected to the contact plug 114. The ball land 118 may be formed on the lower surface of the insulating substrate 112. The ball land 118 may be electrically connected to the contact plug 114. Thus, the bond finger 116 and the ball land 118 may be electrically connected with each other via the contact plug 114.

The dummy finger 120 may be formed on the upper surface of the insulating substrate 112. For example, the dummy finger 120 may include a material that may not be chemically well-bonded to the molding member 160. The dummy finger 120 may include a material which has a poor or inferior chemical bonding characteristic with respect to the molding member 160, and thus may not closely adhered to the molding member 160. For example, the dummy finger 120 may include a metal, e.g., gold. Further, the dummy finger 120 may include a material substantially the same as that of the bond finger 116. Thus, the dummy finger 120 and the bond finger 116 may be formed simultaneously by a single plating process. Accordingly, an additional process for forming the dummy finger 120 is not required. Examples of functions of the dummy finger 120 are illustrated below.

The semiconductor chip 130 may be attached to the upper surface of the package substrate 110 using the die attach film 140. The semiconductor chip 130 may include a bonding pad 132. For example, the bonding pad 132 may be arranged on an upper edge surface of the semiconductor chip 130.

The semiconductor chip 130 may be attached to the package substrate 110 by pressing the semiconductor chip 130 to the die attach film 140 on the upper surface of the package substrate 110. Thus, during pressing the semiconductor chip 130 to the die attach film 140, a void V may be generated in the die attach film 140. Air and/or moisture may be present in the void V. The moisture may expand during a subsequent thermal process (e.g., a reflow process for forming the external terminal 170), thereby causing, e.g., a swelling of the semiconductor package 100.

The conductive wire 150 may electrically connect the bonding pad 132 of the semiconductor chip 130 to the bond finger 116 of the package substrate 110. Thus, the conductive wire 150 may have an upper end connected to the bonding pad 132, and a lower end extended from the upper end and connected to the bond finger 116. An electrical signal may be transmitted between the semiconductor chip 130 and the package substrate 110 through the conductive wire 150. The conductive wire 150 may not be connected to the dummy finger 120. Thus, the electrical signal may not be transmitted through the dummy finger 120. For example, the conductive wire 150 may include a metal such as gold, aluminum, etc.

The molding member 160 may be formed on the upper surface of the package substrate 110 to cover the semiconductor chip 130. The molding member 160 may protect the semiconductor chip 130 and the conductive wire 150 from the external environment. For example, the molding member 160 may include an epoxy molding compound (EMC).

For example, as mentioned above, the dummy finger 120 may include a material which has a poor or inferior chemical bonding characteristic with regard to the molding member. Thus, although the dummy finger 120 may physically contact the molding member 160, the dummy finger 120 may not be closely adhered to the molding member 160. Accordingly, a discharge passageway 122 may be formed between the dummy finger 120 and the molding member 160. The air and/or the moisture in the void V of the die attach film 140 may be released through the discharge passageway 122. Thus, the package substrate 110 may not be expanded by releasing the moisture through the discharge passageway 122. The void V in the die attach film 140 may be removed by releasing the air and/or moisture through the discharge passageway 122.

The external terminal 170 may be mounted on the lower surface of the package substrate 110. For example, the external terminal 170 may include a solder ball. The solder ball may be formed by the reflow process. As mentioned above, because the moisture may be released through the discharge passageway 122 during the reflow process, the package substrate 110 may not be expanded.

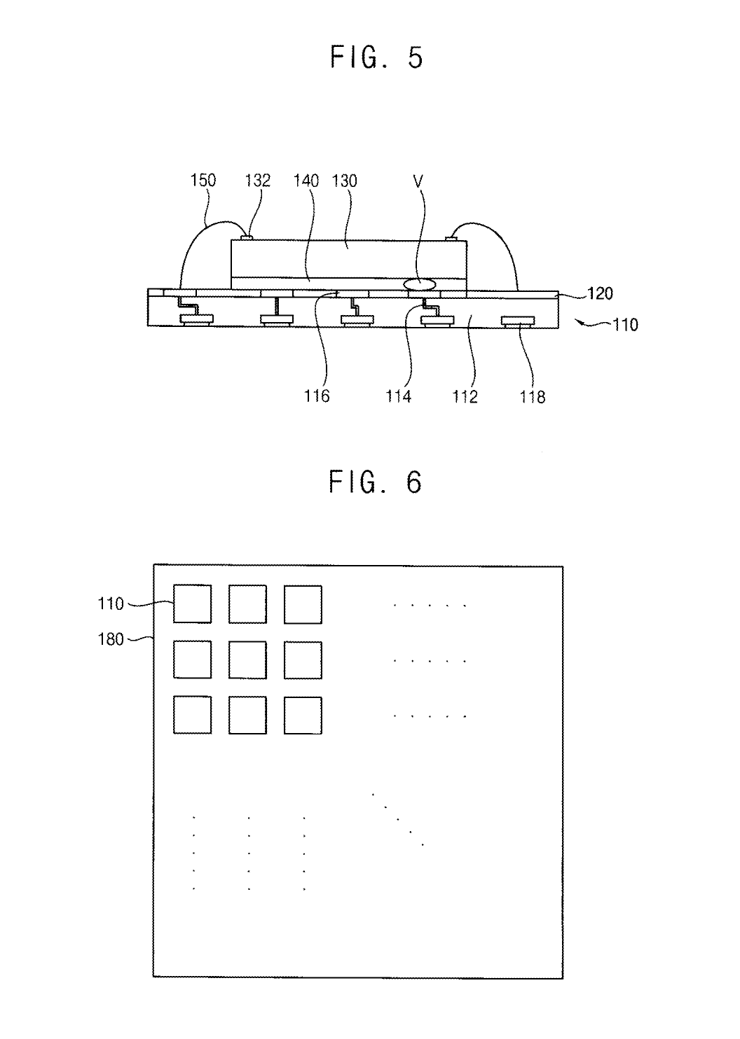

FIGS. 3 to 6 are cross-sectional views and a plan view illustrating a method of manufacturing the semiconductor package in FIG. 1.

Referring to FIG. 3, the contact plug 114 may be formed in the insulating substrate 112. The bonding finger 116 and the dummy finger 120 may be simultaneously formed on the upper surface of the insulating substrate 112 by a plating process. The ball land 118 may be formed on the lower surface of the insulating substrate 112 by a plating process. For example, the bond finger 116, the dummy finger 120 and the ball land 118 may be formed simultaneously with each other by a single plating process.

Referring to FIG. 4, the semiconductor chip 130 may be attached to the upper surface of the package substrate 110 using the die attach film 140. For example, the void V may be formed in the die attach film 140 during attaching the semiconductor chip 130.

Referring to FIG. 5, the bonding pad 132 of the semiconductor chip 130 may be electrically connected to the bond finger 116 of the package substrate 110 using the conductive wire 150.

Referring to FIG. 6, when the above-mentioned processes may be performed on one package substrate 110 and one semiconductor chip 130, a yield of this packaging process may be lowered. According to FIG. 6, a plurality of semiconductor chips 130 may be arranged on a substrate frame 180. The attaching process and the wire bonding process may be performed on the substrate frame 180.

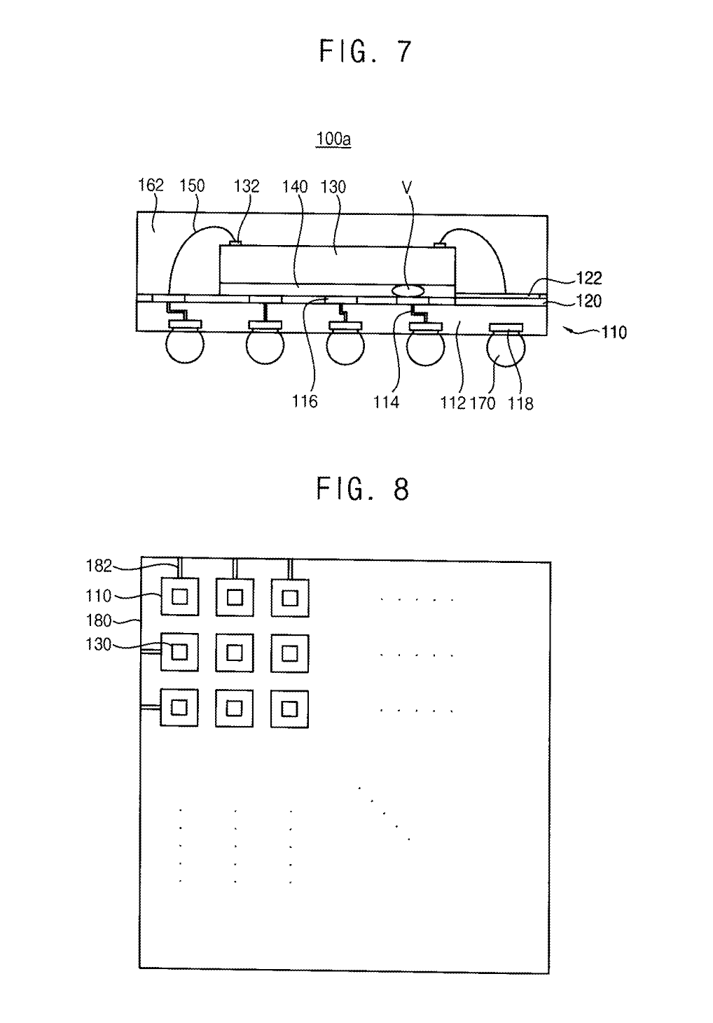

A molding material may be supplied to the substrate frame 180 to mold the semiconductor chips 130 with the molding material, thereby forming the molding member 160. According to one example embodiment, because the dummy finger 120 may not be closely adhered to or chemically well-bonded to the molding member 160, the discharge passageway 122 may be formed between the dummy finger 120 and the molding member 160. Referring to FIG. 7, the molding member 160 may be formed on an edge portion of the substrate frame 180 so that the discharge passageway 122 may be enclosed by the molding member 160.

The substrate frame 180 may be cut such that the substrate frame 180 is separated into individual package substrates 110, each of which including and the semiconductor chip 130. The discharge passageway 122 may be exposed while cutting the molding member 160. Thus, the air and/or the moisture in the void V formed in the die attach film 140 may be released through the discharge passageway 122.

The external terminal 170 may be mounted on the lower surface of the package substrate 110 to complete the semiconductor package 100 in FIG. 1. Alternatively, the external terminal 170 may be mounted on the lower surface of the package substrate 110 before cutting the substrate frame 180.

FIG. 7 is a cross-sectional view illustrating a semiconductor package in accordance with example embodiments.

A semiconductor package 100a according to example embodiments may include elements substantially the same as those of the semiconductor package 100 in FIG. 1 except for a molding member 162. Thus, the same reference numerals refer to the same elements and any further illustrations with respect to the same elements will be omitted herein for brevity.

Referring to FIG. 7, the molding member 162 of the semiconductor package 100a may be configured to enclose the discharge passageway 122. For example, the discharge passageway 122 may extend vertically between the molding layer 162 and the dummy finger 120, and horizontally between the die attach film 140 and an outer surface of the molding member 162, but may not reach the outer surface of the molding member 162. The discharge passageway 122 may been closed by the molding member 162. Thus, the air and/or the moisture may not penetrate into the semiconductor package 100a through the discharge passageway 122 from the environment.

In order for the enclosed discharge passageway 122 to release the air and/or the moisture in the void V, the molding member 162 may be formed to enclose the discharge passageway 122 after releasing the air and/or the moisture in the void V. Releasing the air and/or the moisture in the void V may be illustrated in a following method of manufacturing the semiconductor package 100a.

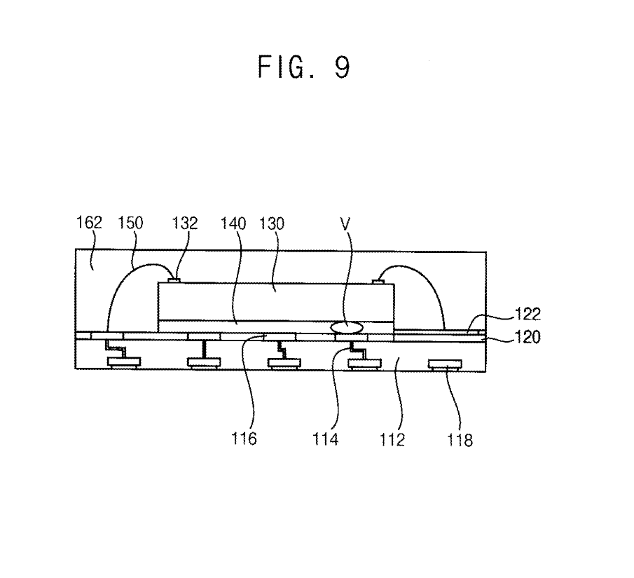

FIGS. 8 and 9 are a cross-sectional view and a plan view illustrating a method of manufacturing the semiconductor package in FIG. 7.

Substantially the same processes as those illustrated with reference to FIGS. 3 to 5 may be performed to attach the semiconductor chip 130 to the upper surface of the package substrate 110 and to electrically connect the semiconductor chip 130 with the package substrate 110.

Referring to FIG. 8, a molding material may be supplied to the substrate frame 180 to mold the semiconductor chips 130 with the molding material, thereby forming the molding member 162. In these example embodiments, because the dummy finger 120 may not be chemically well-bonded to the molding member 162, the discharge passageway 122 may be formed between the dummy finger 120 and the molding member 162.

According to example embodiments, the substrate frame 180 may have a second discharge passageway 182. The second discharge passageway 182 may communicate with the corresponding discharge passageway 122. The second discharge passage way 182 may extend to an outer side surface of the substrate frame 180. Thus, during the molding process, the air and/or the moisture in the void V may be released through the discharge passageway 122 and the second discharge passageway 182.

Referring to FIG. 9, the substrate frame 180 may be cut such that the substrate frame 180 is separated into the individual the package substrate 110 including the semiconductor chip 130. Because the air and/or the moisture in the void V may be previously released through the discharge passageway 122 and the second discharge passageway 128, exposing the discharge passageway 122 may no longer be required. At this stage, the discharge passageway 122 may be enclosed by the molding member 162.

The external terminal 170 may be mounted on the lower surface of the package substrate 110 to complete the semiconductor package 100a in FIG. 7. Alternatively, the external terminal 170 may be mounted on the lower surface of the package substrate 110 before cutting the substrate frame 180.

According to example embodiments, the dummy finger, which may not be chemically bonded to the molding member, may be formed on the package substrate to form the discharge passageway between the molding member and the dummy finger. Thus, the moisture accumulated in the void in the die attach film may be released through the discharge passageway, thereby preventing or mitigating issues, e.g., a swelling of the package substrate, during subsequent heat process, e.g., a reflow process. Further, the air accumulated in the void may also be released through the discharge passageway, thereby removing or reducing the void in the die attach film. Furthermore, because the dummy finger and the bond finger may be formed by the single plating process, an additional process for forming the dummy finger may not be required.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor package comprising:
a package substrate including at least one bond finger;
a semiconductor chip on the upper surface of the package substrate, the semiconductor chip electrically connected to the bond finger;
a die attach film between the semiconductor chip and the package substrate, the die attach film attaching the semiconductor chip to the package substrate;
a molding member on the upper surface of the package substrate, the molding member covering the semiconductor chip; and
at least one dummy finger between the upper surface of the package substrate and the molding member.

2. The semiconductor package of claim 1, wherein the at least one dummy finger and the molding member are configured to not closely adhere to each other such that at least one discharge passageway is formed therebetween.

3. The semiconductor package of claim 2, wherein the at least one dummy finger extends from the die attach film to an outer surface of the molding member, and the at least one discharge passageway is exposed through the outer surface of the molding member.

4. The semiconductor package of claim 2, wherein the at least one discharge passageway extends between the die attach film and an outer surface of the molding member, and one end of the at least one discharge passageway is enclosed by the molding member.

5. The semiconductor package of claim 1, wherein the at least one dummy finger includes a metal.

6. The semiconductor package of claim 1, wherein the at least one dummy finger and the at least one bond finger includes substantially a same material.

7. The semiconductor package of claim 1, further comprising:
a conductive wire configured to electrically connect the semiconductor chip to the at least one bond finger.

8. The semiconductor package of claim 1, further comprising:
an external terminal on a lower surface of the package substrate.

9. A method of manufacturing a semiconductor package, the method comprising:
forming at least one bond finger on an upper surface of a package substrate;
forming at least one dummy finger on the upper surface of the package substrate;
attaching a semiconductor chip to the upper surface of the package substrate using a die attach film;
electrically connecting the semiconductor chip with the at least one bond finger; and
forming a molding member on the upper surface of the package substrate to cover the semiconductor chip and the at least one dummy finger,
wherein the at least one dummy finger includes a material that does not closely adhere to the molding member to format least one first discharge passageway between the at least one dummy finger and the molding member.

10. The method of claim 9, further comprising performing a heat process to release air or moisture in a void, which is formed in the die attach film, through the at least one first discharge passageway.

11. The method of claim 10, wherein forming the molding member includes:
arranging a plurality of the package substrates on a substrate frame;
forming the molding member on the package substrates; and
separating the substrate frame into individual package substrates, wherein the at least one first discharge passageway of each of the individual package substrate is exposed through an outer surface of the molding member.

12. The method of claim 10, wherein forming the molding member includes:
arranging a plurality of the package substrates on a substrate frame, the substrate frame having at least one second discharge passageway, the at least one second passageway in communication with the at least one first discharge passageway;
forming the molding member on the package substrates with releasing the air or the moisture in the void through the at least one first discharge passageway and the at least one second discharge passageway;
separating the substrate frame into individual package substrates; and
enclosing the at least one first discharge passageway.

13. The method of claim 9, wherein the at least one bond finger and the at least one dummy finger are formed simultaneously.

14. The method of claim 13, wherein the at least one bond finger and the at least one dummy finger are formed simultaneously by a single plating process.

15. The method of claim 9, further comprising:
forming a conductive wire electrically connecting the semiconductor chip to the at least one bond finger.

16. A semiconductor package comprising:
a package substrate including at least one bond finger;
a semiconductor chip on the bond finger, the semiconductor chip electrically connected to the package substrate through the bond finger;
a die attach film between the semiconductor chip and the package substrate, the die attach film attaching the semiconductor chip to the package substrate;
a molding member on the package substrate; and
at least one dummy finger between the package substrate and the molding member and surrounding the die attach film, the at least one dummy finger configured to not closely adhere to the molding member to provide at least one discharge passage between the at least one dummy finger and the molding member.

17. The semiconductor package of claim 16, wherein one end of the at least one discharge passageway is exposed through an outer surface of the molding member.

18. The semiconductor package of claim 16, wherein the at least one discharge passageway facing an outer surface of the molding member is enclosed.

19. The semiconductor package of claim 18, wherein the at least one discharge passageway facing an outer surface of the molding member is enclosed by the molding member.

20. The semiconductor package of claim 16, wherein the at least one dummy finger and the at least one bond finger includes substantially a same material.
